(19) United States
(12) Patent Application Publication
(10) Pub. No.: US 2026/0190765 A1
(43) Pub. Date: Jul. 2, 2026

(54) DISPLAY DEVICE

(71) Applicant: LG Display Co., Ltd., Seoul (KR)

(72) Inventor: JunJae LEE, Paju-si (KR)

(73) Assignee: LG Display Co., Ltd., Seoul (KR)

(21) Appl. No.: 19/431,020

(22) Filed: Dec. 23, 2025

(30) Foreign Application Priority Data
Dec. 31, 2024 (KR) 10-2024-0202266

(51) Int. Cl. H10K 59/80; H10K 77/10; H10K 102/00

(52) U.S. Cl. CPC H10K 59/871; H10K 77/111; H10K 2102/311; H10K 2102/351

(57) ABSTRACT

A display device according to one or more examples includes a substrate, a display area in which a plurality of pixels is disposed, a first non-display area outside the display area, a bending area extending from one side of the first non-display area, a second non-display area connected to the bending area, a back plate disposed on the substrate to support the substrate, and a support plate disposed on the back plate and having a plurality of holes disposed in the curved area.

### CROSS-REFERENCE TO RELATED APPLICATIONS

This application claims the benefit of and priority to Korean Patent Application No. 10-2024-0202266 filed on Dec. 31, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device with improved reliability.

### 2. Description of Related Art

Currently, as it enters a full-fledged information era, the field of display devices that visually display electrical information signals is rapidly developing, and research is being conducted to develop performances such as thinning, weight reduction, and low power consumption for various display devices.

Among these various display devices, a light emitting display device is a self-emitting display device, and unlike a liquid crystal display device, a separate light source is not required, so that the light emitting display device may be manufactured to have a light weight and a small thickness. In addition, the light emitting display device is advantageous in terms of power consumption because the light emitting display device operates at a low voltage. Further, the light emitting display device is expected to be utilized in various fields because the light emitting display device is excellent in color implementation, a response speed, a viewing angle, and a contrast ratio (CR).

The description of related art should not be considered prior art merely because it is mentioned in or associated with this section. The description of related art includes information that describes one or more aspects of the subject technology, and the description in this section does not limit the scope of the present disclosure.

### SUMMARY

An aspect of the present disclosure provides a display device which minimizes concentration of stress on a partial area in a structure in which a bezel area is bent in a curved shape.

Another aspect of the present disclosure provides a display device capable of improving rigidity of a support plate in a structure in which a bezel area is bent in a curved shape.

Still another aspect of the present disclosure provides a display device which can easily discharge electro static discharge (ESD).

Aspects of the present disclosure are not limited to the above-mentioned aspects, and other aspects, which are not mentioned above, can be clearly understood by those skilled in the art from the present disclosure.

A display device according to one or more example embodiments of the present disclosure includes a substrate, a display area in which a plurality of pixels is disposed, a first non-display area surrounding the display area, a bending area extending from one side of the first non-display area, a second non-display area connected to the bending area, a back plate disposed on the substrate to support the substrate, and a support plate disposed on the back plate and having a plurality of holes disposed in a curved area.

A display device according to one or more example embodiments of the present disclosure includes a substrate, a display area including a first display area having a flat surface and a second display area having a curved surface, a first non-display area outside the display area, a bending area extended from one side of the first non-display area and bent, a second non-display area connected to the bending area, a back plate disposed on the substrate and supporting the substrate, a first support plate disposed on the back plate, and a second support plate disposed on the first support plate and having a plurality of holes disposed in the second display area.

Other detailed matters of the example embodiments are included in the detailed description and the drawings.

According to one or more aspects of the present disclosure, a hole is formed in a support plate disposed in an area in which a bezel area is bent in a curved shape so that even though the hole is bent in a curved shape, the stress is concentrated only in a partial area (or a localized area), which improves the reliability.

According to one or more aspects of the present disclosure, the portion where the hole of the support plate is not formed is disposed so as to correspond to the edge of the display device to ensure the rigidity of the support plate. Therefore, it is possible to minimize the damage to the display device by reducing the concentration of impact on the edge of the display device even with an external impact.

According to one or more aspects of the present disclosure, a conductive adhesive layer is bonded to a support plate made of a metal material to enhance an electro static discharge (ESD) path and facilitate ESD discharge.

The effects according to one or more aspects of the present disclosure are not limited to the contents described above, and other effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic view of a display device according to an example embodiment of the present disclosure.

FIG. 2 is a plan view of the display device according to the example embodiment of the present disclosure before bending.

FIG. 3 is a rear view of the display device according to the example embodiment of the present disclosure after bending.

FIG. 4 is an example of a cross-sectional view taken along the line A-A′ of FIG. 3.

FIG. 5 is an example of an enlarged plan view of the support plate of FIG. 3.

FIG. 6 is an example of a plan view illustrating another shape of a support plate.

FIG. 7 is a plan view of a display device according to another example embodiment of the present disclosure.

FIG. 8 is a plan view of a display device according to still another example embodiment of the present disclosure.

FIG. 9 is a plan view of a display device according to still another example embodiment of the present disclosure.

FIG. 10 is a cross-sectional view of a display device according to still another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural, and vice versa, unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “contacts,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

Unless stated otherwise, the terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, Unless stated otherwise, the terms “first direction,” “second direction,” “third direction,” “X direction,” “Y direction,” “Z direction,” “bending direction,” “extension direction” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, unless stated otherwise, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, unless stated otherwise, at least one of a plurality of elements can represent (i) one element of the plurality of elements, (ii) some elements of the plurality of elements, or (iii) all elements of the plurality of elements. Further, unless stated otherwise, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, unless stated otherwise, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

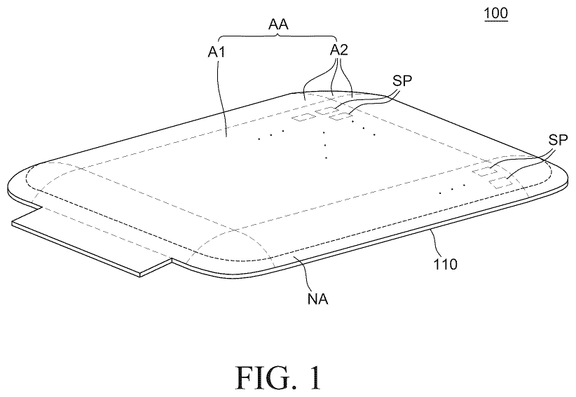

FIG. 1 is a schematic view of a display device according to an example embodiment of the present disclosure. In FIG. 1, for the convenience of description, among various components of the display device 100, only a substrate 110 is illustrated.

Referring to FIG. 1, a display device 100 according to an example embodiment of the present disclosure may include a substrate 110.

The substrate 110 may be a component for supporting various components included in the display device 100. A light emitting element for displaying an image, a driving circuit for driving the light emitting element, and wiring lines for transmitting various signals to the light emitting element and the driving circuit may be disposed on the substrate 110.

In one or more examples, the display device 100 may include a display area AA and a non-display area NA. In one or more examples, the substrate 110 may include the display area AA and the non-display area NA.

The display area AA is an area in which images are displayed. In the active area AA, a plurality of sub pixels SP constituting a plurality of pixels and a driving circuit for driving the plurality of sub pixels SP may be disposed.

The plurality of sub-pixels SP is a minimum unit constituting the display area AA, and a light emitting element may be disposed in each of the plurality of sub-pixels SP. For example, an organic light-emitting element including an anode, an organic light-emitting layer, and a cathode may be disposed in each of the plurality of sub-pixels SP, but it is not limited thereto. Further, a driving circuit for driving the plurality of sub-pixels SP may include a driving element, a wiring line, and the like. For example, the driving circuit may be configured by a thin film transistor, a storage capacitor, a gate line, a data line, and the like, but is not limited thereto.

The display area AA may include a first display area A1 and a second display area A2.

The first display area A1 may be an area formed by or having a flat surface, and the second display area A2 may be an area formed by or having a curved surface. For example, the first display area A1 may be referred to as a flat portion, and the second display area A2 may be referred to as a curved portion or a bending portion. For example, the second display area A2 is disposed in the upper portion, the lower portion, both side portions, and the corner of the first display area A1 so that the slope may increase as the distance from the first display area A1 increases. However, the present disclosure is not limited thereto, and the second display areas A2 disposed on the upper portion, the lower portion, and both side portions of the first display area A1 may be disposed with different curvatures. In addition, the second display area A2 may be disposed on only one side of the first display area A1 or on all sides of the first display area A1. For example, when the first display area A1 has four sides, the second display area A2 may be disposed on one or more sides of four sides, or as shown in FIG. 1, all sides and corners of four sides, but is not limited thereto.

The second display area A2 may be a display area in which the sub-pixels SP are disposed in all or a part of the second display area A2, and the entirety or a part of the second display area A2 may be configured as a part of the display area AA, but is not limited thereto. When a part of the second display area A2 is configured as the display area AA, the remaining part of the second display area A2 may be configured as a part of the non-display area NA.

The non-display area NA is an area where an image is not displayed. For instance, the non-display area NA may be configured as an outer portion of the substrate 110 surrounding the display area AA or may be configured as an area outside the display area AA. In the non-display area NA, various wiring lines and circuits for driving the organic light emitting element of the display area AA may be disposed. For example, in the non-display area NA, a link line for transmitting signals to the plurality of sub pixels SP and the driving circuit of the display area AA or a driving integrated circuit (IC) D-IC, such as a gate driver IC and a data driver IC, may be disposed, but it is not limited thereto. The non-display area NA may extend from the display area AA formed as (or having) a curved surface. The slope of the non-display area NA may increase as the distance from the display area AA increases.

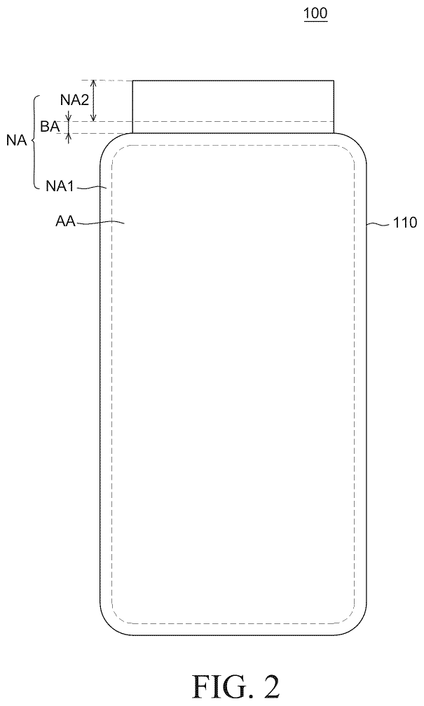

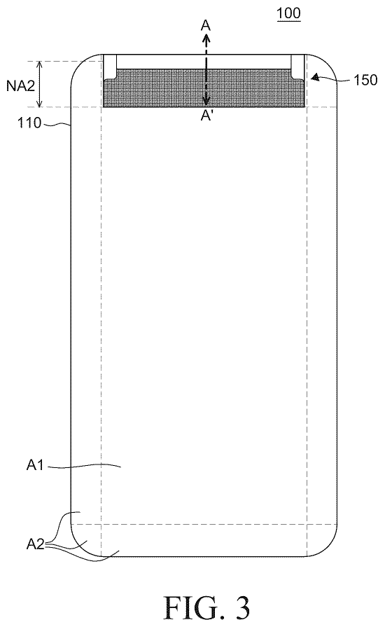

FIG. 2 is a plan view of the display device according to the example embodiment of the present disclosure before bending. FIG. 3 is a rear view of the display device according to the example embodiment of the present disclosure after bending. FIG. 2 illustrates a front surface of the substrate 110 before bending, and FIG. 3 illustrates a rear surface of the substrate 110 after bending.

Referring to FIGS. 2 and 3, the substrate 110 may include a display area AA and a non-display area NA.

The non-display area NA may include a first non-display area NA1, a bending area BA, and a second non-display area NA2.

The first non-display area NA1 may be an area that surrounds the display area AA and extends from the display area AA.

The bending area BA is an area extending from one side of the first non-display area NA1 and may be an area bent in a bending direction.

The second non-display area NA2 may be an area extending from the bending area BA and disposed below the substrate 110 during bending or after bending.

A second support plate 150 may be disposed on the substrate 110 to support the substrate 110. For example, the second support plate 150 may be disposed and supported in a part of the display area AA and the first non-display area NA1, and the second non-display area NA2 and the second support plate 150 may be disposed to overlap each other. A plurality of holes 154 may be disposed in the second support plate 150.

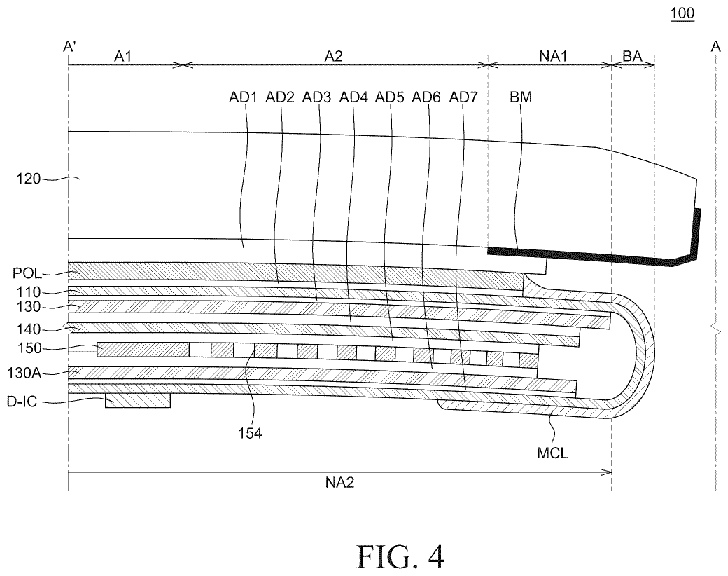

FIG. 4 is an example of a cross-sectional view taken along the line A-A′ of FIG. 3.

Referring to FIG. 4, the display device 100 according to one or more aspects of the present disclosure may include a substrate 110, a cover window 120, a polarizer POL, a back plate 130, a first support plate 140, a second support plate 150, an additional back plate 130A, and a micro coating layer MCL.

The substrate 110 is a component for supporting various components included in the display device 100 and may be made of an insulating material. For example, the substrate 110 may be a glass substrate made of a plastic material such as polyimide (PI) or glass.

The cover window 120 may be disposed on the front surface of the substrate 110. The cover window 120 may be a component exposed from the outside of the display device 100 and protects the display device 100 from external impacts and scratches. Further, the cover window 120 may protect the display device 100 from moisture permeating from the outside. The cover window 120 may be formed of glass or a plastic material having flexibility, but is not limited thereto.

A black matrix BM is disposed below the cover window 120. The black matrix BM may be disposed along the circumference of the cover window 120 at the outer periphery of the cover window 120. The black matrix BM may be formed of a material having low permeability. Accordingly, the black matrix BM may prevent various components disposed under the black matrix BM from being visually recognized to the outside. Further, the black matrix BM may be formed of a conductive material to discharge static electricity of the cover window 120.

The black matrix BM may be composed of chromium (Cr), graphite, or resin containing conductive particles. Here, the resin may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. In addition, the conductive particles may be formed of any one of molybdenum (Mo), chromium (Cr), titanium (Ti), nickel (Ni), neodymium (Nd), copper (Cu), and an alloy of silver (Ag) and magnesium (Mg), but are not limited thereto.

A polarizing plate POL may be disposed between the substrate 110 and the cover window 120. The polarization plate POL may be disposed on the entire surface of the substrate 110. The polarization plate POL selectively transmits light to reduce reflection of external light incident on the substrate 110. Specifically, the substrate 110 may include various metal materials applied to semiconductor devices, wiring lines, organic light emitting devices, and the like. Therefore, the external light incident onto the substrate 110 may be reflected from the metal material, and the visibility of the display device 100 may be reduced due to the reflection of the external light. On the other hand, when the polarization plate POL is disposed, the polarization plate POL suppresses the reflection of external light to increase the outdoor visibility of the display device 100. However, the polarization plate POL may be omitted depending on the design of the display device 100, but is not limited thereto.

The first adhesive layer AD1 may be disposed between the polarization plate POL and the cover window 120, and the second adhesive layer AD2 may be disposed between the polarization plate POL and the substrate 110. The first adhesive layer AD1 may bond the cover window 120 and the polarization plate POL, and the second adhesive layer AD2 may bond the polarization plate POL and the substrate 110. The first adhesive layer AD1 and the second adhesive layer AD2 may be formed of a transparent adhesive layer so that the image of the substrate 110 is visible. For example, the first adhesive layer AD1 and the second adhesive layer AD2 may be formed of an optical clear adhesive (OCA), but are not limited thereto.

The back plate 130 may be disposed on a lower surface of the substrate 110. The back plate 130 may be disposed to support the substrate 110. For example, when the substrate 110 is made of a plastic material such as polyimide, a separate component for protecting the substrate 110 may be required due to the flexible characteristics. Accordingly, a support substrate made of glass is disposed under the substrate 110 to perform a manufacturing process of the display device 100, and after the manufacturing process is completed, the support substrate may be separated and released. However, since a component for supporting the substrate 110 is required even after the support substrate is released, the back plate 130 for supporting the substrate 110 may be disposed on the bottom surface of the substrate 110.

The back plate 130 may include a plastic material. For example, the back plate 130 may be formed of a plastic thin film formed of polyimide (PI), polyethylene naphthalate (PEN), polyethylene terephthalate (PET), or a combination of these polymers.

A third adhesive layer AD3 is disposed between the substrate 110 and the back plate 130. The third adhesive layer AD3 may bond the substrate 110 and the back plate 130. The third adhesive layer AD3 may be formed of a pressure sensitive adhesive (PSA), but is not limited thereto.

Support plates 140 and 150 may be disposed on the lower surface of the back plate 130.

The support plates 140 and 150 may include a first support plate 140 and a second support plate 150. The first support plate 140 and the second support plate 150 are disposed between the back plate 130 and the additional back plate 130A to support the back plate 130 and the additional back plate 130A and fix the back plate 130 and the additional back plate 130A.

The first support plate 140 may be disposed below the back plate 130. For example, the first support plate 140 may be disposed on a lower surface of the back plate 130.

The first support plate 140 may protect the components of the display device 100 from an external impact. Further, the first support plate 140 serves as a ground to suppress static electricity permeating into the display device 100 or to easily discharge residual electric charges accumulated in the display device 100 to the outside. In addition, the first support plate 140 may easily dissipate heat generated from the display device 100 to the outside. The first support plate 140 may be formed of a metal material having excellent thermal conductivity, electrical conductivity, and mechanical rigidity. For example, the first support plate 140 may be made of copper (Cu) or stainless steel (SUS), but is not limited thereto.

A fourth adhesive layer AD4 may be disposed between the back plate 130 and the first support plate 140. The fourth adhesive layer AD4 may bond the back plate 130 and the first support plate 140. The fourth adhesive layer AD4 may be made of pressure sensitive adhesive (PSA), but is not limited thereto.

The second support plate 150 may be disposed below the first support plate 140. For example, the second support plate 150 may be disposed on a lower surface of the first support plate 140.

The second support plate 150 may protect the components of the display device 100 from external impacts. Further, the second support plate 150 serves as a ground to suppress static electricity permeating the display device 100 or to easily discharge residual electric charges accumulated in the display device 100 to the outside. In addition, the second support plate 150 may easily dissipate heat generated from the display device 100 to the outside. The second support plate 150 may be formed of a metal material having excellent thermal conductivity, electrical conductivity, and mechanical rigidity. For example, the second support plate 150 may be made of copper (Cu) or stainless steel (SUS), but is not limited thereto.

The thickness of the second support plate 150 may be thicker than the thickness of the first support plate 140. For example, the thickness of the second support plate 150 disposed therebelow may be thicker than the first support plate 140 disposed thereabove. This means that when an external impact is applied to the front surface of the display device 100, that is, an upper portion of the display device 100, the impact is concentrated on the impact applied point. When the thickness of the second support plate 150 disposed at the lower portion is thicker than that of the first support plate 140 disposed at the upper portion, the rigidity of the rear surface of the display device 100 increases, which may reduce the stress applied to the display device 100.

A plurality of holes 154 may be disposed in the second support plate 150. A plurality of holes 154 may be disposed in a curved area (or in or on a curved area of the substrate 110). Details of the second support plate 150 and a plurality of holes 154 will be described later.

A fifth adhesive layer AD5 may be disposed between the first support plate 140 and the second support plate 150. The fifth adhesive layer AD5 may bond the first support plate 140 and the second support plate 150. The fifth adhesive layer AD5 may be formed of a pressure sensitive adhesive (PSA), but is not limited thereto.

An additional back plate 130A may be disposed below the second support plate 150.

The additional back plate 130A may be disposed in the second non-display area NA2 of the substrate 110 to reinforce the rigidity of the second non-display area NA2. Meanwhile, the additional back plate 130A may be disposed so as not to overlap the bending area BA. Accordingly, the thickness of the components disposed in the bending area BA may be minimized, and the neutral plane of the bending area BA may be easily controlled, thereby securing the flexibility of the bending area BA.

A sixth adhesive layer AD6 may be disposed between the second support plate 150 and the additional back plate 130A. The sixth adhesive layer AD6 may bond the second support plate 150 and the additional back plate 130A. For example, the sixth adhesive layer AD6 may be made of pressure sensitive adhesive (PSA), but is not limited thereto.

A second non-display area NA2 of the bent substrate 110 may be disposed below the additional back plate 130A. Further, a seventh adhesive layer AD7 may be disposed between the additional back plate 130A and the second non-display area NA2 of the substrate 110. The seventh adhesive layer AD7 may bond the additional back plate 130A and the second non-display area NA2 of the substrate 110. For example, the seventh adhesive layer AD7 may be formed of pressure sensitive adhesive (PSA), but is not limited thereto.

A micro coating layer MCL may be disposed in the bending area BA of the substrate 110.

The micro coating layer MCL may be a component for protecting components disposed in the bending area BA of the substrate 110, for example, various wiring lines.

A tensile force is applied to the bending area BA of the substrate 110 so that components may be cracked. Therefore, the micro coating layer MCL is coated on the components disposed in the bending area BA of the substrate 110 with a thin thickness to protect the components disposed in the bending area BA. The micro coating layer MCL may be formed of resin and for example, may be formed of an acrylic material such as acrylate polymer, but is not limited thereto.

Hereinafter, the second support plate 150 will be described in detail with reference to the drawings.

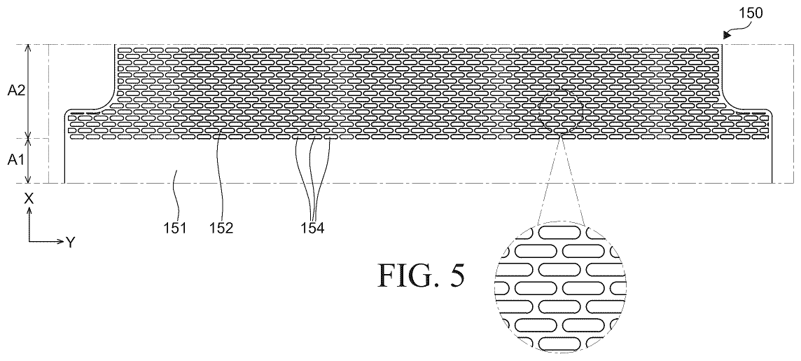

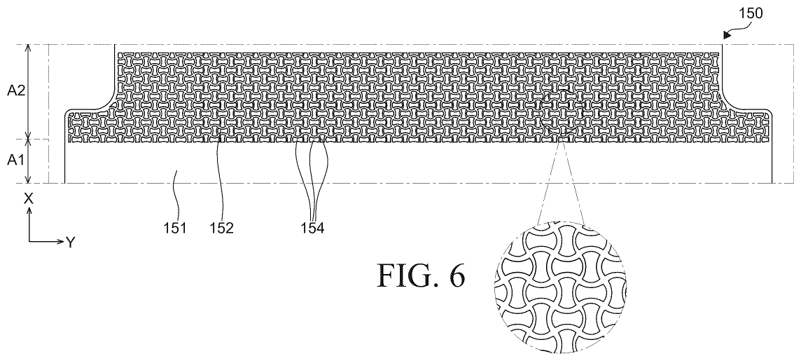

FIG. 5 is an example of an enlarged plan view of the support plate of FIG. 3. FIG. 6 is an example of a plan view illustrating another shape of a support plate. In FIGS. 5 and 6, only the second support plate 150 is illustrated.

Referring to FIGS. 4 and 5, the second support plate 150 may be disposed at a position corresponding to the second non-display area NA2 (or the second non-display area NA2 of the substrate 110) to support the substrate 110.

For example, the second support plate 150 may be disposed at a position corresponding to a part of the first display area A1, the second display area A2, and a part of the first non-display area NA1 to support the substrate 110. In the area in which the second support plate 150 is not disposed, the fifth adhesive layer AD5 and the sixth adhesive layer AD6 may be directly bonded. However, the present disclosure is not limited thereto, and the second support plate 150 may be disposed only at positions corresponding to the second display area A2 and a part of the first non-display area NA1.

For example, the second support plate 150 may be disposed between the back plate 130 and the additional back plate 130A that support and fix the substrate 110 to support the back plate 130 and the additional back plate 130A and fix the back plate 130 and the additional back plate 130A. Accordingly, the second support plate 150 may be made of a material having rigidity to reinforce the substrate 110 having a flexible characteristic. For example, the second support plate 150 may be formed of a metal such as copper (Cu) or stainless steel (SUS), but is not limited thereto.

The second support plate 150 may include a first portion 151 and a second portion 152.

The first portion 151 of the second support plate 150 may partially overlap the first display area A1. The first portion 151 of the second support plate 150 may have a flat shape. The first portion 151 of the second support plate 150 may have a planar shape corresponding to the first display area A1. Therefore, the first portion 151 of the second support plate 150 may reinforce the first display area A1 which is a flat area of the substrate 110.

The second portion 152 of the second support plate 150 may extend from the first portion 151 and may be bent. The second portion 152 of the second support plate 150 may be, have, provide, or form a curved area. The second portion 152 of the second support plate 150 may overlap the second display area A2. The second portion 152 of the second support plate 150 may have a curved shape corresponding to the second display area A2. The second portion 152 of the second support plate 150 may be bent to correspond to the second display area A2.

Both sides of the second support plate 150 may be curved along the shapes of the bending area BA and the second non-display area NA2 of the substrate 110, but are not limited thereto.

A plurality of holes 154 may be disposed in the second portion 152 of the second support plate 150. The plurality of holes 154 may be disposed from a boundary between the first display area A1 and the second display area A2 to an end of the second support plate 150. For example, the plurality of holes 154 may be disposed from a boundary between the first display area A1 and the second display area A2 to a position overlapping a part of the first non-display area NA1. In an example, the plurality of holes 154 may be disposed from a boundary between the first display area A1 and the second display area A2 to a position overlapping a part of the first non-display area NA1 and a part of the second non-display area NA2. In an example, the plurality of holes 154 may be disposed from a boundary between the first display area A1 and the second display area A2 to a position corresponding to an end of the second support plate 150. In an example, the plurality of holes 154 may be disposed from a boundary between the first display area A1 and the second display area A2 to a position corresponding to an end of the second display area A2.

A plurality of holes 154 may allow the second support plate 150 to have flexibility. The plurality of holes 154 may be disposed in the second portion 152 of the second support plate 150 to be spaced apart from each other by a predetermined interval in the first direction (X direction) and the second direction (Y direction).

A plurality of holes 154 may be alternately disposed with a plurality of holes 154 disposed adjacent to each other in the first direction. Specifically, centers of a plurality of holes 154 disposed adjacent to each other in the first direction may be alternately disposed.

In some examples, the plurality of holes 154 may be arranged in multiple rows in a staggered pattern, with alternating rows having aligned centers. In an example, the plurality of holes 154 may be arranged in multiple rows, with the centers of the plurality of holes 154 in adjacent rows staggered so that alternate rows are aligned. In an example, the plurality of holes 154 may be disposed in multiple rows in an alternating, staggered arrangement, such that the centers of the plurality of holes 154 in alternate rows align while the centers the plurality of holes 154 in the intermediate rows are offset.

The planar shape of the plurality of holes 154 may be a shape extending in a direction (Y direction) orthogonal to the bending direction (X direction). For example, a planar shape of each of the plurality of holes 154 may be an oval shape, a Bunimovich Stadium shape, a rectangular shape, or the like. In addition, as shown in FIG. 6, it may be formed in a radial pattern shape or an orthogonal pattern shape.

In the case of a display device in which a bezel area is bent in a curved shape, stress is increased in the curved bezel area so that lines and insulating layers constituting a substrate of the display device are peeled off or plates adhered between the substrates are peeled off.

Accordingly, in the display device 100 according to the example embodiment of the present disclosure, the second support plate 150 is disposed in an area overlapping the second non-display area NA2 of the substrate 110 adjacent to the bending area BA, and the second support plate 150 is composed of a first portion 151 overlapping the first display area A1 having a planar shape and a second portion 152 overlapping the second display area A2 having a curved shape. A plurality of holes 154 are formed in the second portion 152 but not in the first portion 151 of the second support plate 150. Accordingly, when the substrate 110 overlapping the second display area A2 is bent to correspond to the curved shape of the second display area A2, the second portion 152 of the second support plate 150 is also bent in the same manner. In this case, the deformation of the second support plate 150 is facilitated by the plurality of holes 154, thereby minimizing the occurrence of stress due to the deformation of the second support plate 150. Accordingly, in the display device 100 according to the example embodiment of the present disclosure, a plurality of holes 154 are formed in the second support plate 150 which is disposed so as to correspond to an area in which the bezel area is bent in a curved shape to minimize the stress applied to the bezel area even though the bezel area of the display device 100 is bent in a curved shape. Therefore, it is possible to minimize the concentration of stress on only a partial area (or a localized area) of the bezel area to suppress the peeling of each component of the display device 100 and improve the reliability of the display device 100.

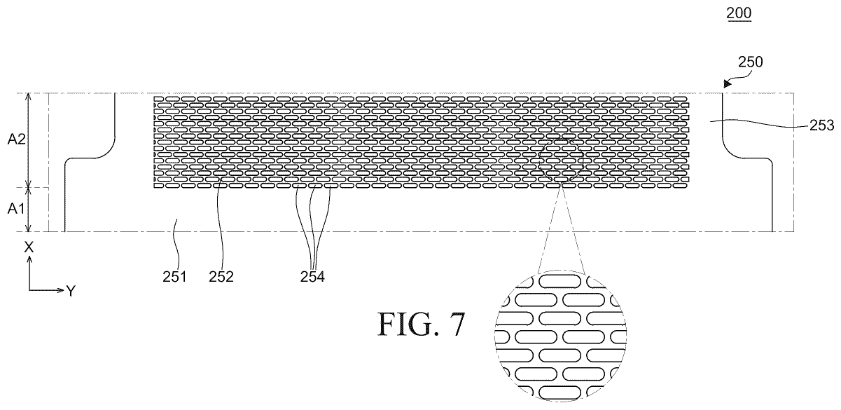

FIG. 7 is a plan view of a display device according to another example embodiment of the present disclosure. FIG. 7 is an enlarged plan view of the second support plate 250. In FIG. 7, only the second support plate 250 is illustrated. In FIG. 7, the remaining configurations excluding the second support plate 250 are the same as those in FIGS. 1 to 6. Therefore, the descriptions provided for the display device 100 and its components with respect to FIGS. 1 to 6 apply to the display device 200 and its components of FIG. 7 (excluding the second support plate 250), and a redundant description is omitted for brevity. It should be noted that some of the descriptions of the second support plate 150 may apply to the second support plate 250, except as otherwise described with respect to the second support plate 250.

Referring to FIG. 7, the second support plate 250 of the display device 200 according to another example embodiment of the present disclosure may be disposed at positions corresponding to the first display area A1 and the second display area A2 to support the substrate 110.

The second support plate 250 may include a first portion 251, a second portion 252, and a third portion 253.

The first portion 251 may overlap the first display area A1. The first portion 251 may have a flat shape. The first portion 251 may have a planar shape corresponding to the first display area A1. Accordingly, the first portion 251 may reinforce the first display area A1, which is a flat area of the substrate 110.

The second portion 252 may extend from the first portion 251 and may be disposed to be bent. The second portion 252 may be, have, provide, or form a curved area. The second portion 252 may overlap the second display area A2. The second portion 252 may be formed in a curved shape corresponding to the second display area A2.

A plurality of holes 254 may be disposed in the second portion 252. The plurality of holes 254 may be disposed from the boundary between the first display area A1 and the second display area A2 to an end (e.g., to an end of the second support plate 250). For example, the plurality of holes 254 may be disposed from a boundary between the first display area A1 and the second display area A2 to a position overlapping an end of the second display area A2. For example, the plurality of holes 254 may be disposed from a boundary between the first display area A1 and the second display area A2 to a position overlapping a part of the first non-display area NA1 and the second non-display area NA2.

The third portion 253 may be disposed on both sides of the second portion 252. The third portion 253 may be, have, provide, or form a curved area. The third portion 253 may overlap the second display area A2. The third portion 253 may be disposed in an area overlapping a predetermined area on both sides of the substrate 110. The third portion 253 may be an area in which a plurality of holes 254 are not disposed.

Accordingly, in the display device 200 according to another example embodiment of the present disclosure, a plurality of holes 254 are formed or provided in the second support plate 250 disposed in an area in which the bezel area is bent in or into a curved shape to minimize the stress applied to the bezel area even though the bezel area of the display device 200 is bent in a curved shape. By minimizing concentration of stress on only a partial area (or a localized area) of the bezel area, peeling of each component of the display device 200 may be prevented, and the reliability of the display device 200 may be improved.

On the other hand, in the case of a display device in which the bezel area is bent in a curved shape, when an external impact is applied, there is a problem in that the impact is concentrated in an area corresponding to both side portions of the substrate in the bezel area and stress is concentrated only in a partial area.

Accordingly, in the display device 200 according to another example embodiment of the present disclosure, the second support plate 250 is disposed in an area corresponding to the second non-display area NA2 (or the second non-display area NA2 of the substrate 110). The second support plate 250 includes a first portion 251 overlapping the planar first display area A1, a second portion 252 overlapping the curved second display area A2, and a third portion 253 disposed on both sides of the second portion 252. A plurality of holes 254 are formed in the second portion 252, and a plurality of holes 254 are not formed in the first portion 251 or the third portion 253. Accordingly, when the substrate 110 overlapping the second display area A2 is bent to correspond to the curved shape of the second display area A2, the second portion 252 and the third portion 253 are also bent in the same manner. In this case, it is possible to reinforce an area adjacent to both side portions of the substrate 110 by the third portion 253 in which the plurality of holes 254 is not disposed while being easily deformed by the plurality of holes 254 disposed in the second portion 252. When an external impact occurs, it is possible to minimize the concentration of stress on only a partial area of the bezel area corresponding to both side portions of the substrate 110, thereby preventing the peeling of each component of the display device 200 and improving the reliability of the display device 200. Accordingly, in the display device 200 according to another example embodiment of the present disclosure, the third portion 253 in which the plurality of holes 254 is not formed is disposed so as to correspond to an area adjacent to both side portions of the substrate 110 to ensure the rigidity of the corresponding area. Therefore, it is possible to minimize the concentration of impact on both edges of the display device 200 even with an external impact, thereby minimizing the breakage of the display device.

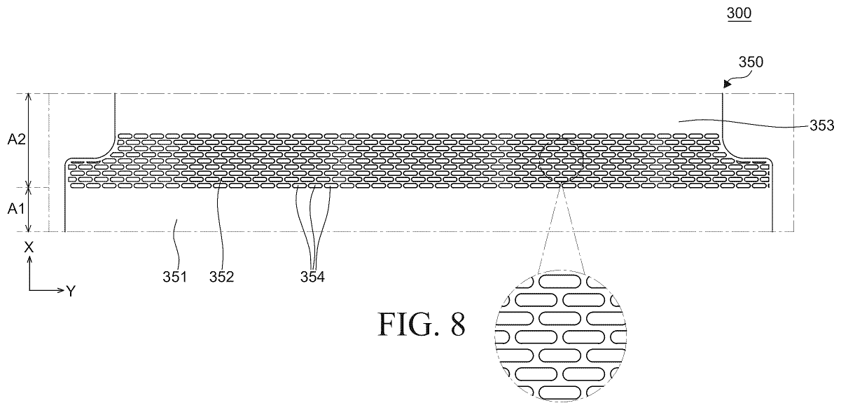

FIG. 8 is a plan view of a display device according to still another example embodiment of the present disclosure. FIG. 8 is an enlarged plan view of the second support plate 350. FIG. 8 illustrates only the second support plate 350. In FIG. 8, the remaining configurations excluding the second support plate 350 are the same as those in FIGS. 1 to 7. Therefore, the descriptions provided for the display device 100 and 200 and its components with respect to FIGS. 1 to 7 apply to the display device 300 and its components of FIG. 8 (excluding the second support plate 350), and a redundant description is omitted for brevity. It should be noted that some of the descriptions of the second support plate 150 and 250 may apply to the second support plate 350, except as otherwise described with respect to the second support plate 350.

Referring to FIG. 8, the second support plate 350 of the display device 300 according to still another example embodiment of the present disclosure may be disposed at positions corresponding to the first display area A1 and the second display area A2 to support the substrate 110.

The second support plate 350 may include a first portion 351, a second portion 352, and a third portion 353.

The first portion 351 may overlap the first display area A1. The first portion 351 may have a flat shape. The first portion 351 may have a planar shape corresponding to the first display area A1. Accordingly, the first portion 351 may reinforce the first display area A1, which is a flat area of the substrate 110.

The second portion 352 may extend from the first portion 351 and may be disposed to be bent. The second portion 352 may be, have, provide, or form a curved area. The second portion 352 may overlap the second display area A2. The second portion 352 may have a curved shape corresponding to the second display area A2.

A plurality of holes 354 may be disposed in the second portion 352. For example, the plurality of holes 354 may be disposed from a boundary between the first display area A1 and the second display area A2 to an interior position (or a partial position) of the second display area A2. For example, the plurality of holes 354 may be disposed (i) starting at a boundary between the first display area A1 and the second display area A2 and (ii) extending to a position that is between the boundary and an end of the second display area A2 (e.g., extending to a position that is midway between the boundary and an end of the second display area A2).

The third portion 353 may extend from the second portion 352 to the end of the second support plate 350 (or the end of the second display area A2) and may be disposed to be bent. The third portion 353 may be a curved area overlapping a portion of the second display area A2. The third portion 353 may be an area in which a plurality of holes 354 are not disposed.

Accordingly, in the display device 300 according to still another example embodiment of the present disclosure, the second support plate 350 is disposed in an area corresponding to the second non-display area NA2 (or the second non-display area NA2 of the substrate 110). The second support plate 350 includes a first portion 351 which overlaps the planar first display area A1, a second portion 352 which overlaps the curved second display area A2, and a third portion 353 which overlaps the second display area A2 and extends from the second portion 352. A plurality of holes 354 are formed in the second portion 352, and a plurality of holes 354 are not formed in the first portion 351 or the third portion 353. Accordingly, when the substrate 110 overlapping the second display area A2 is bent to correspond to the curved shape of the second display area A2, the second portion 352 and the third portion 353 are also bent in the same manner. In this case, the deformation may be facilitated by the plurality of holes 354 disposed in the second portion 352, and an area adjacent to the end of the substrate 110 may be reinforced by the third portion 353 in which the plurality of holes 354 is not disposed. Further, when an external impact occurs, stress is minimized only in a partial area of the bezel area corresponding to the end of the substrate 110 to suppress the peeling of each component of the display device 300 and improve the reliability of the display device 300. Accordingly, in the display device 300 according to still another example embodiment of the present disclosure, the third portion 353 in which the plurality of holes 354 is not formed is disposed so as to correspond to an area adjacent to the end of the substrate 110 to ensure the rigidity of the corresponding area. Therefore, it is possible to minimize the concentration of impact on both edges of the display device 300 even with an external impact, thereby minimizing the breakage of the display device.

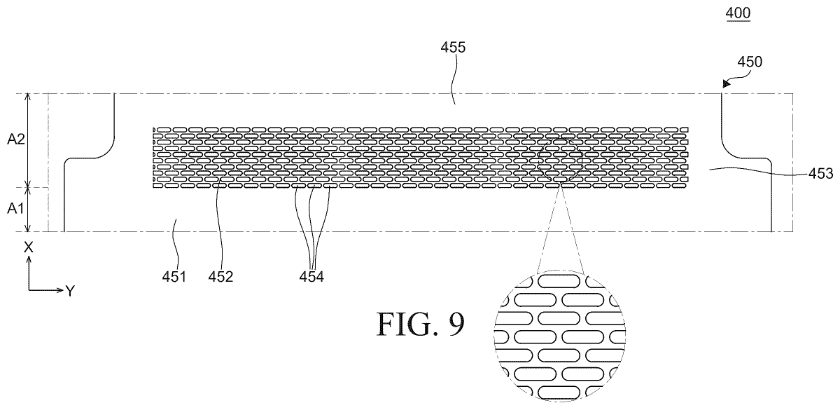

FIG. 9 is a plan view of a display device according to still another example embodiment of the present disclosure. FIG. 9 is an enlarged plan view of the second support plate 450. FIG. 9 illustrates only a second support plate 450. In FIG. 9, the remaining configurations excluding the second support plate 450 are the same as those in FIGS. 1 to 8. Therefore, the descriptions provided for the display device 100, 200 and 300 and its components with respect to FIGS. 1 to 8 apply to the display device 400 and its components of FIG. 9 (excluding the second support plate 450), and a redundant description is omitted for brevity. It should be noted that some of the descriptions of the second support plate 150, 250 and 350 may apply to the second support plate 450, except as otherwise described with respect to the second support plate 450.

Referring to FIG. 9, the second support plate 450 of the display device 400 according to still another example embodiment of the present disclosure may be disposed at positions corresponding to the first display area A1 and the second display area A2 to support the substrate 110.

The second support plate 450 may include a first portion 451, a second portion 452, a third portion 453, and a fourth portion 455.

The first portion 451 may overlap the first display area A1. The first portion 451 may have a flat shape. The first portion 451 may have a planar shape corresponding to the first display area A1. Accordingly, the first portion 451 may reinforce the first display area A1, which is a flat area of the substrate 110.

The second portion 452 may extend from the first portion 451 and may be bent. The second portion 452 may be, have, provide, or form a curved area. The second portion 452 may overlap the second display area A2. The second portion 452 may have a curved shape corresponding to the second display area A2.

A plurality of holes 454 may be disposed in the second portion 452. For example, the plurality of holes 454 may be disposed from a boundary between the first display area A1 and the second display area A2 to an interior position (or a partial position) of the second display area A2.

The third portion 453 may be disposed on both sides of the second portion 452. The third portion 453 may be, have, provide, or form a curved area. The third portion 453 may overlap the second display area A2. The third portion 453 may be disposed in an area overlapping a predetermined area on both sides of the substrate 110. The third portion 453 may be an area in which a plurality of holes 454 are not disposed.

The fourth portion 455 may extend from the second portion 452 and the third portion 453 to an end of the second support plate 450 (or the end of the second display area A2) and may be disposed to be bent. The fourth portion 455 may be a curved area overlapping a portion of the second display area A2. The fourth portion 455 may be an area in which a plurality of holes 454 are not disposed.

Accordingly, in the display device 400 according to still another example embodiment of the present disclosure, the second support plate 450 is disposed in an area corresponding to the second non-display area NA2 (or the second non-display area NA2 of the substrate 110). The second support plate 450 includes a first portion 451 which overlaps the planar first display area A1, a second portion 452 which overlaps the curved second display area A2, a third portion 453 disposed on both sides of the second portion 452, and a fourth portion 455 which extends from the second portion 452 and the third portion 453 to the end of the second support plate 450 (or the end of the second display area A2). A plurality of holes 454 is formed in the second portion 452, and a plurality of holes 454 is not formed in the first portion 451, the third portion 453, and the fourth portion 455. Accordingly, when the substrate 110 overlapping the second display area A2 is bent to correspond to the curved shape of the second display area A2, the second portion 452, the third portion 453, and the fourth portion 455 are also bent in the same manner. In this case, the third portion 453 and the fourth portion 455, in which the plurality of holes 454 is not disposed, may reinforce an area adjacent to both side portions of the substrate 110 and an area adjacent to an end of the substrate 110 while being easily deformed by the plurality of holes 454 disposed in the second portion 452. Further, when an external impact occurs, stress is minimized only in a partial area of the bezel area corresponding to both side portions and ends of the substrate 110 to suppress the peeling of each component of the display device 400 and improve the reliability of the display device 400. Accordingly, in the display device 400 according to still another example embodiment of the present disclosure, the third portion 453 in which the plurality of holes 454 is not formed is disposed to correspond to an area adjacent to both side portions of the substrate 110, and the fourth portion 455 is disposed to correspond to an area adjacent to the end of the substrate 110 to ensure the rigidity of the corresponding area. Therefore, it is possible to minimize the concentration of impact on both edges of the display device 400 even under an external impact, thereby minimizing the damage to the display device.

Referring to FIGS. 5 to 9, in some examples, a second portion of a second support plate having a plurality of holes is more flexible than a first portion, a third portion, or a fourth portion of the second support plate. For example, a second portion 152, 252, 352 or 452 of a respective second support plate 150, 250, 350 or 450 that contains a respective plurality of holes 154, 254, 354 or 454 is more flexible than a respective first portion 151, 251, 351 or 451, a respective third portion 253, 353 or 453, or a respective fourth portion 455.

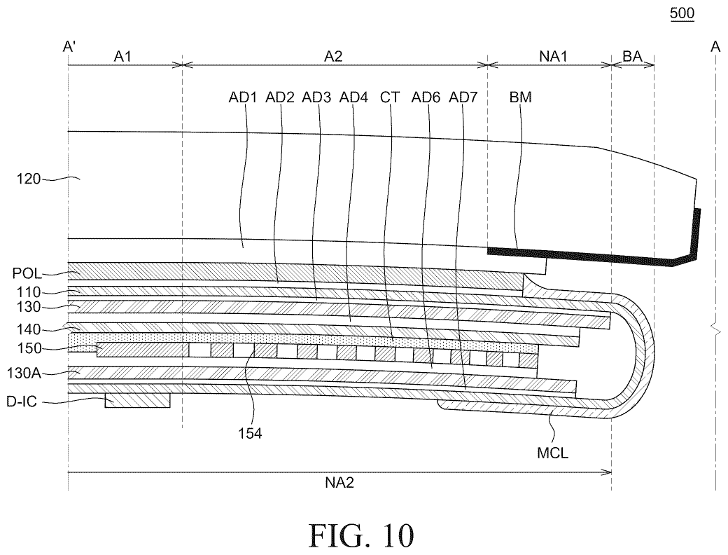

FIG. 10 is a cross-sectional view of a display device according to still another example embodiment of the present disclosure. FIG. 10 is a cross-sectional view of the same position as A-A′ of FIG. 3. In FIG. 10, the configurations excluding the conductive adhesive layer CT are the same as those of FIG. 4. Therefore, the descriptions provided for the display device 100 and its components with respect to FIGS. 1 to 4 apply to the display device 500 and its components of FIG. 10 (excluding the conductive adhesive layer CT), and a redundant description is omitted for brevity.

Referring to FIG. 10, in the display device 500 according to still another example embodiment of the present disclosure, a conductive adhesive layer CT may be disposed between the first support plate 140 and the second support plate 150. For example, the conductive adhesive layer CT may be disposed on the entire surface between the first support plate 140 and the second support plate 150 or may be disposed only in a portion between the first support plate 140 and the second support plate 150.

The conductive adhesive layer CT may be made of a conductive material and discharge static electricity of the first support plate 140 and the second support plate 150 made of a metal material. For example, the conductive adhesive layer CT may be made of a resin including conductive particles. Here, the resin may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. In addition, the conductive particles may be formed of any one of molybdenum (Mo), chromium (Cr), titanium (Ti), nickel (Ni), neodymium (Nd), copper (Cu), and an alloy of silver (Ag) and magnesium (Mg), but are not limited thereto.

Accordingly, in the display device 500 according to still another example embodiment of the present disclosure, the conductive adhesive layer CT may be disposed between the first support plate 140 and the second support plate 150 made of a metal material. As a result, the electro static discharge (ESD) path through which the stators of the first support plate 140 and the second support plate 150 are discharged may be strengthened, and ESD discharge of the first support plate 140 and the second support plate 150 may be facilitated.

In some examples, unless stated otherwise, an end of the substrate 110 may correspond to or may refer to an end of the second support plate 150, 250, 350 or 450, but it is not limited thereto.

Various examples and aspects of the present disclosure are described below. These are provided as examples, and do not limit the scope of the present disclosure.

A display device according to one or more example embodiments of the present disclosure includes a substrate, a display area in which a plurality of pixels is disposed, a first non-display area outside the display area, a bending area extending from one side of the first non-display area, a second non-display area connected to the bending area, a back plate disposed on the substrate to support the substrate, and a support plate disposed on the back plate and having a plurality of holes disposed in a curved area.

According to one or more aspects of the present disclosure, the display area includes a first display area having a flat surface and a second display area having of a curved surface, and the plurality of holes may be disposed in an area overlapping the second display area.

According to one or more aspects of the present disclosure, the plurality of holes may be disposed from the boundary between the first display area and the second display area to the end of the support plate.

According to one or more aspects of the present disclosure, the support plate may include a first part which overlaps the first display area and in which a plurality of holes are not disposed, a second part which extends from the first part, which overlaps the second display area, and in which a plurality of holes are disposed, and a third part disposed on both sides of the second part and in which a plurality of holes are not disposed.

According to one or more aspects of the present disclosure, the support plate may include a first part which overlaps the first display area and in which a plurality of holes are not disposed, a second part which extends from the first part, which overlaps the second display area, and in which a plurality of holes are disposed, and a third part which extends from the second part to an end of the support plate and in which a plurality of holes are not disposed.

According to one or more aspects of the present disclosure, the support plate may include a first portion which overlaps the first display area and in which the plurality of holes are not disposed, a second portion which extends from the first portion, which overlaps the second display area and in which the plurality of holes are disposed, a third portion which is disposed on both sides of the second portion and in which the plurality of holes are not disposed, and a fourth portion which extends from the second portion to an end of the support plate and in which the plurality of holes are not disposed.

According to one or more aspects of the present disclosure, the support plate may include a first support plate disposed in the display area and the first non-display area and a second support plate spaced apart from the first support plate and disposed in the second non-display area, and the plurality of holes may be disposed in the second support plate.

According to one or more aspects of the present disclosure, the thickness of the second support plate may be thicker than the thickness of the first support plate.

According to one or more aspects of the present disclosure, the first support plate and the second support plate may be formed of a metal material, and a conductive adhesive layer may be formed of a conductive material and may be disposed between the first support plate and the second support plate.

According to one or more aspects of the present disclosure, the substrate is bent in a first direction, and the plurality of holes may be disposed along an extension direction that is orthogonal to the first direction.

According to one or more aspects of the present disclosure, the plurality of holes may be arranged in multiple rows in a staggered pattern, with alternating rows having aligned centers.

According to one or more aspects of the present disclosure, the plurality of holes may have a planar shape in any one of an oval shape, a Bunimovich Stadium shape, a rectangular shape, a radial pattern shape, and an orthogonal pattern.

A display device according to one or more example embodiments of the present disclosure includes a substrate, a display area including a first display area having of a flat surface and a second display area having a curved surface, a first non-display area outside the display area, a bending area extended from one side of the first non-display area and bent, a second non-display area connected to the bending area, a back plate disposed on the substrate and supporting the substrate, a first support plate disposed on the back plate, and a second support plate disposed on the first support plate and having a plurality of holes disposed in the second display area.

According to one or more aspects of the present disclosure, the second support plate may include a first part which overlaps the first display area and in which a plurality of holes are not disposed, a second part which extends from the first part, which overlaps the second display area, and in which a plurality of holes are disposed, and a third part which is disposed on both sides of the second part and in which a plurality of holes are not disposed.

According to one or more aspects of the present disclosure, the second support plate may include a first portion which overlaps the first display area and in which a plurality of holes are not disposed, a second portion which extends from the first portion, which overlaps the second display area, and in which a plurality of holes are disposed, and a third portion which extends from the second portion to an end of the second support plate and in which a plurality of holes are not disposed.

According to one or more aspects of the present disclosure, the second support plate may include a first portion which overlaps the first display area and in which the plurality of holes are not disposed, a second portion which extends from the first portion, which overlaps the second display area, and in which the plurality of holes are disposed, a third portion which is disposed on both sides of the second portion and in which the plurality of holes are not disposed, and a fourth portion which extends from the second portion to an end of the second support plate and in which the plurality of holes are not disposed.

According to one or more aspects of the present disclosure, the thickness of the second support plate may be thicker than the thickness of the first support plate.

According to one or more aspects of the present disclosure, the first support plate and the second support plate may be formed of a metal material, and a conductive adhesive layer may be formed of a conductive material and may be disposed between the first support plate and the second support plate.

A display device according to one or more example embodiments of the present disclosure includes a display area configured to display an image, and a non-display area outside the display area, wherein the non-display area comprises a first non-display area extending from the display area, a bending area extending from the first non-display area, and a second non-display area extending from the bending area, and wherein the display device further includes a substrate overlapping the second non-display area, and a support plate disposed on the substrate, having a curved portion in the second non-display area, and having a plurality of holes in the curved portion.

According to one or more aspects of the present disclosure, the support plate has a flat portion in which the plurality of holes are not disposed.

According to one or more aspects of the present disclosure, the substrate is configured to be bent in the bending area and overlaps the bending area, and the support plate overlaps at least a portion of the display area, overlaps at least a portion of the first non-display area, and does not overlap the bending area.

Although the example embodiments of the present disclosure have been described in detail with reference to the accompanying drawings, the present disclosure is not limited thereto and may be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present invention. The protective scope of the present disclosure should be construed based on the following claims, and all the technical concepts in the equivalent scope thereof should be construed as falling within the scope of the present disclosure.

What is claimed is:

1. A display device, comprising:
a substrate;
a display area in which a plurality of pixels is disposed, a first non-display area outside the display area, a bending area extending from one side of the first non-display area and bent, and a second non-display area connected to the bending area;
a back plate disposed on the substrate and supporting the substrate; and
a support plate disposed on the back plate and having a plurality of holes disposed in a curved area.

2. The display device according to claim 1, wherein the display area includes a first display area having a flat surface and a second display area having a curved surface, and
wherein the plurality of holes are disposed in an area overlapping the second display area.

3. The display device according to claim 2, wherein the plurality of holes are disposed from a boundary between the first display area and the second display area to an end of the support plate.

4. The display device according to claim 2, wherein the support plate includes:
a first part which overlaps the first display area and in which the plurality of holes are not disposed;
a second part which extends from the first part, which overlaps the second display area, and in which the plurality of holes are disposed; and
a third part which is disposed on both sides of the second part and in which the plurality of holes are not disposed.

5. The display device according to claim 2, wherein the support plate includes:
a first part which overlaps the first display area and in which the plurality of holes are not disposed;
a second part which extends from the first part, which overlaps the second display area, and in which the plurality of holes are disposed; and
a third part which extends from the second part to an end of the support plate and in which the plurality of holes are not disposed.

6. The display device according to claim 2, wherein the support plate includes:
a first part which overlaps the first display area and in which the plurality of holes are not disposed;
a second part which extends from the first part, which overlaps the second display area, and in which the plurality of holes are disposed;
a third part which is disposed on both sides of the second part, and in which the plurality of holes are not disposed; and
a fourth part which extends from the second part to an end of the support plate and in which the plurality of holes are not disposed.

7. The display device according to claim 1, wherein the support plate includes:
a first support plate disposed in the display area and the first non-display area; and
a second support plate spaced apart from the first support plate and disposed in the second non-display area, and
wherein the plurality of holes are disposed in the second support plate.

8. The display device according to claim 7, wherein a thickness of the second support plate is greater than a thickness of the first support plate.

9. The display device according to claim 7, wherein the first support plate and the second support plate are formed of a metal material, and
wherein a conductive adhesive layer is formed of a conductive material and is disposed between the first support plate and the second support plate.

10. The display device according to claim 1, wherein the substrate is bent in a first direction, and
wherein the plurality of holes are disposed along an extension direction that is orthogonal to the first direction.

11. The display device according to claim 1, wherein the plurality of holes are arranged in multiple rows in a staggered pattern, with alternating rows having aligned centers.

12. The display device according to claim 1, wherein the plurality of holes has a planar shape formed of any one of an oval shape, a Bunimovich Stadium shape, a rectangular shape, a radial pattern shape, and an orthogonal pattern.

13. A display device, comprising:
a substrate;
a display area including a first display area having a flat surface and a second display area having a curved surface, a first non-display area outside the display area, a bending area extending from one side of the first non-display area, and a second non-display area connected to the bending area;
a back plate disposed on the substrate to support the substrate;
a first support plate disposed on the back plate; and
a second support plate disposed on the first support plate and having a plurality of holes disposed in the second display area.

14. The display device according to claim 13, wherein the second support plate includes
a first part which overlaps the first display area and in which the plurality of holes are not disposed;
a second part which extends from the first part, which overlaps the second display area, and in which the plurality of holes are disposed; and
a third part which is disposed on both sides of the second part and in which the plurality of holes are not disposed.

15. The display device according to claim 13, wherein the second support plate includes
a first part which overlaps the first display area and in which the plurality of holes are not disposed;
a second part which extends from the first part, which overlaps the second display area, and in which the plurality of holes are disposed; and
a third part which extends from the second part to an end of the second support plate and in which the plurality of holes are not disposed.

16. The display device according to claim 13, wherein the second support plate includes:
a first part which overlaps the first display area and in which the plurality of holes are not disposed;
a second part which extends from the first part, which overlaps the second display area, and in which the plurality of holes are disposed;
a third part which is disposed on both sides of the second part and in which the plurality of holes are not disposed; and
a fourth part which extends from the second part to an end of the second support plate and in which the plurality of holes are not disposed.

17. The display device according to claim 13, wherein a thickness of the second support plate is greater than a thickness of the first support plate,
wherein the first support plate and the second support plate are formed of a metal material, and wherein a conductive adhesive layer is formed of a conductive material and is disposed between the first support plate and the second support plate.

18. A display device, comprising:
a display area configured to display an image;
a non-display area outside the display area, the non-display area comprising a first non-display area extending from the display area, a bending area extending from the first non-display area, and a second non-display area extending from the bending area;
a substrate overlapping the second non-display area; and
a support plate disposed on the substrate, having a curved portion in the second non-display area, and having a plurality of holes in the curved portion.

19. The display device according to claim 18, wherein the support plate has a flat portion in which the plurality of holes are not disposed.

20. The display device according to claim 18, wherein the substrate is configured to be bent in the bending area and overlaps the bending area, and
wherein the support plate overlaps at least a portion of the display area, overlaps at least a portion of the first non-display area, and does not overlap the bending area.
